(19) United States
(12) Patent Application Publication
(10) Pub. No.: US 2010/0285398 A1
(43) Pub. Date: Nov. 11, 2010

(54) TAMPER INDICATING ARTICLE

(75) Inventors: Peter B. Hogerton, White Bear Lake, MN (US); Thomas P. Hanschen, Mendota Heights, MN (US); Patrick R. Fleming, Lake Elmo, MN (US); James M. Jonza, Woodbury, MN (US); David M. Moses, Woodbury, MN (US); Dale L. Ehnes, Cotati, CA (US); Jingjing Ma, Cottage Grove, MN (US)

Correspondence Address: 3M INNOVATIVE PROPERTIES COMPANY, PO BOX 33427, ST. PAUL, MN, 55133-3427, US

(73) Assignee: 3M INNOVATIVE PROPERTIES COMPANY, ST. PAUL, MN (US)

(21) Appl. No.: 12/599,774

(22) PCT Filed: May 15, 2008
(86) PCT No.: PCT/US08/63631

§ 371 Date: Jul. 28, 2010

Related U.S. Application Data
(60) Provisional application No. 60/938,837, filed on May 18, 2007.
(60) Provisional application No. 60/987,529, filed on Nov. 13, 2007.

(51) Int. Cl. G03F 7/00; B44F 1/10

(52) U.S. Cl. 430/2; 428/29

(57) ABSTRACT

Tamper indicating articles that include a surface-feature image-generating layer and an adhesive layer are described. The surface-feature image-generating layer generates a visible, surface-feature-generated image upon exposure to light. The intensity of the surface-feature-generated image is reduced when taped-over. Single-image and dual-image tamper indicating articles are also described, including buried dual-image and adjacent dual-image tamper indicating articles.

### CROSS REFERENCE TO RELATED APPLICATIONS

This application claims the benefit of U.S. Provisional Patent Application No. 60/938,837, filed May 18, 2007, and U.S. Provisional Patent Application No. 60/987,529, filed Nov. 13, 2007, the disclosures of which are incorporated by reference herein in their entirety.

### FIELD

The present disclosure relates to tamper indicating articles that include a tape-over detection feature. The tampering indicating articles include at least one surface-feature-generated image. Single-image and dual-image tamper indicating articles are described. The dual-image tamper indicating articles include adjacent dual-image and buried dual-image tamper indicating articles. Exemplary articles include tapes and labels.

### SUMMARY

Briefly, in one aspect, the present disclosure provides a tamper indicating article. In some embodiments, the tamper indicating article comprises a substrate comprising a first major surface and an opposite second major surface; a surface-feature image-generating layer associated with the first major surface of the substrate; and an adhesive layer associated with the second major surface of the substrate. In some embodiments, the surface-feature image-generating layer generates a visible, surface-feature-generated image upon exposure to visible light.

In another aspect, the present disclosure provides a dual-image tamper indicating article. In some embodiments, the buried, dual-image, tamper-indicating article comprising a substrate comprising a first major surface and an opposite second major surface; a surface-feature image-generating layer associated with the first major surface of the substrate; and an adhesive layer associated with the second major surface of the substrate; wherein the surface-feature image-generating layer generates a surface-feature-generated image upon interaction with light; and a buried image at least partially obscured by the first, surface-feature-generated image.

In yet another aspect, the present disclosure provides an adjacent, dual-image tamper-indicating article comprising: a substrate comprising a first major surface and an opposite second major surface; a first surface-feature image-generating layer associated with a first portion of the first major surface of the substrate, wherein the first surface-feature image-generating layer generates a first, surface-feature-generated image upon interaction with light; a second surface-feature image-generating layer associated with a second portion of the first major surface of the substrate, wherein the second surface-feature image-generating layer generates a second, surface-feature-generated image upon interaction with light; and an adhesive layer associated with the second major surface.

In some embodiments, the surface tension of the first surface-feature image-generating layer is greater than the surface tension of the second surface-feature image-generating layer. In some embodiments, an average feature size of the first surface-feature image-generating layer is greater than an average feature size of the second surface-feature image-generating layer. In some embodiments, the features comprise grooves, and the average feature size is the average groove depth or the average groove frequency. In some embodiments, the features comprise particles, and the average feature size is the average major axis of the particles.

Regardless of the particular aspect of the disclosure, in some embodiments, the tamper indicating article further comprises at least one of a contrast layer, a refractive index modifying layer covering the first surface-feature image-generating layer, and a surface energy modifying layer covering the first surface-feature image-generating layer. In some embodiments, the first surface-feature image-generating layer has been treated to alter its surface energy.

In some embodiments, the surface-feature image-generating layer is integral to the first major surface of the substrate. In some embodiments, the surface-feature image-generating layer comprises a resin layer associated with the first major surface of the substrate. In some embodiments, surface-feature image-generating layer has a refractive index of between 1.4 and 1.5, inclusive.

Regardless of whether the surface-feature image-generating layer is integral to or associated with the first major surface of the substrate, in some embodiments, the visible, surface-feature-generated image may comprise a hologram, a matte appearance, or combinations thereof.

In some embodiments, the article further comprises at least one functional layer associated with the surface-feature image-generating layer. In some embodiments, the functional layer may be a release layer, a hard coat, or may provide both functions. In some embodiments, both a release layer and a hard coat may be present.

In some embodiments, the adhesive layer may be directly bonded to the second major surface of the substrate. In some embodiments, the tamper indicating article may comprise a contrast layer located between the second major surface of the substrate and the adhesive layer. In some embodiments, the contrast layer may comprise a reflective layer. In some embodiments, the contrast layer may comprise a metal, metal oxide, metal sulfide, and combinations thereof. In some embodiments, the contrast layer comprises at least one of a dye or a pigment. In some embodiments, metals, metal oxides, metal sulfides, and combinations thereof may be used in combination with dyes and/or pigments.

In some embodiments, the surface-feature image-generating layer is associated with a first portion of the first major surface of the substrate. In some embodiments, the surface-feature image-generating layer comprises an embossed layer. In some embodiments the surface-feature image-generating layer comprises inorganic particles dispersed in an organic resin.

In some embodiments, at least 80% of the features of the surface-feature image-generating layer have a minimum z-axis dimension of at least 90 nanometers. In some embodiments, at least 80% of the features of the surface-feature image-generating layer have a maximum z-axis dimension of no greater than 5 micrometers. In some embodiments, at least 80% of the features of the surface-feature image-generating layer have a z-axis dimension of between 0.09 micrometers and 2 micrometers.

In some embodiments, the surface-feature image-generating layer generates a visible, surface-feature-generated image upon exposure to diffuse, visible light.

The above summary of the present disclosure is not intended to describe each embodiment of the present invention. The details of one or more embodiments of the invention are also set forth in the description below. Other features, objects, and advantages of the invention will be apparent from the description and from the claims.

### BRIEF DESCRIPTION OF THE DRAWINGS

FIG. 1a illustrates an exemplary single-image tamper indicating article according to some embodiments of the present disclosure.

FIG. 1b is a cross-section view of the tamper indicating article of FIG. 1a.

FIG. 2 illustrates the effect of tape-over on the surface-feature-generated image on the tamper indicating article of FIGS. 1a and 1b.

FIG. 3a illustrates another exemplary single-image tamper indicating article according to some embodiments of the present disclosure.

FIG. 3b is a cross-section view of the tamper indicating article of FIG. 3a.

FIG. 4a illustrates yet another exemplary single-image tamper indicating article according to some embodiments of the present disclosure.

FIG. 4b illustrates the effect of tape-over on the surface-feature-generated image on the tamper indicating article of FIG. 4a.

FIG. 5 illustrates an exemplary buried, dual-image tamper indicating article according to some embodiments of the present disclosure.

FIG. 6 illustrates another exemplary buried, dual-image tamper indicating article according to some embodiments of the present disclosure.

FIG. 7a illustrates a cross-section of an exemplary adjacent, dual-image tamper indicating article according to some embodiments of the present disclosure.

FIG. 7b illustrates another view of the adjacent, dual-image tamper indicating article of FIG. 7a.

FIG. 7c illustrates the effect of tape-over on the surface-feature-generated image on the tamper indicating article of FIGS. 7a and 7b.

FIG. 8a illustrates another exemplary embodiment of an adjacent, dual-image tamper indicating article according to some embodiments of the present disclosure.

FIG. 8b illustrates the effect of tape-over on the surface-feature-generated image on the tamper indicating article of FIG. 8a.

### DETAILED DESCRIPTION

A wide variety of goods are shipped in sealed containers, e.g., corrugated boxes. Often the seams of the container are closed with an adhesive tape, e.g., a sealing tape. During distribution of the container, there is a risk that an unauthorized person may open the container to, e.g., tamper with or remove some or all of the goods in the container. As efforts to tamper with or remove items from sealed containers becomes more prevalent, there is an ongoing need to develop more sophisticated tamper-proof and/or tamper indicating sealing devices.

For example, one crude method of unauthorized opening includes removing the sealing tape, tampering with the contents, and resealing the container with the original piece of tape. Such methods can be deterred by selecting a sealing tape that results in the destruction of the tape or container upon removal of the sealing tape.

If only the sealing tape is damaged upon removal, another approach to container tampering includes removing the sealing tape, tampering with the contents of the container, and resealing the container with a new piece of tape. In some cases this approach can be deterred by including an image with the sealing tape. To make duplication of the tape more difficult, holograms may be included with the sealing tape.

In situations where the sealing tape is difficult to duplicate, the unauthorized opener may simply slit the sealing tape with, e.g., a razor, open the container, and reseal the opening by applying a second piece of tape over the original sealing tape. When the image included with the original sealing tape is still visible through the second piece of tape, it is often difficult to detect such tape-over during routine inspections of the containers during shipment or at delivery.

Generally, the tamper indicating articles of the present disclosure comprise a substrate having a surface-feature image-generating layer associated with a first major surface of the substrate. Exemplary tamper indicating articles of the present disclosure include adhesive articles such as labels and tapes. Such adhesive articles generally include an adhesive layer associated with a second major surface of the substrate, which is opposite the first major surface.

As used herein, the term “surface features” refers to spatial variations in the surface of a layer. Characteristics of particular spatial variations include height, depth, width, aspect ratio, and frequency. These characteristics are discussed in detail below. As used herein, a layer having a surface that includes “surface features” will be referred to as a “textured” layer.

As used herein, an image is “surface-feature-generated” when a visible image is generated by the interaction of light with the surface features defining the boundary between the textured layer and its adjacent layer or ambient environment (typically air) that results from the differences in their respective refractive indices. Surface-feature-generated images include images resulting from diffraction, refraction, and combinations thereof. In addition, reflection generally impacts the intensity of the surface-feature-generated image.

As used herein, the term “visible image” refers to a distinct appearance that may be perceived by the human eye under the desired lighting conditions. In some embodiments, the image may be perceptible when the textured surface is exposed to visible light (e.g., light having a wavelength of about 380-780 nanometers (nm)). In some embodiments, the image will be visible under diffuse lighting conditions, as arises when the surface is viewed under solar lighting and/or room lighting including, e.g., incandescent and fluorescent lighting. In some embodiments, a collimated light source may be required. In some embodiments, the visible image may be a simple matte appearance. In some embodiments, the visible image may be a complex hologram.

In summary, a “surface-feature image-generating layer” is a layer having surface features, wherein the interaction of light with the surface features generates a visible image resulting from the difference between the refractive index of the textured layer and the layer or ambient environment (e.g., air) adjacent the textured layer.

As used herein, a layer is “associated with” a surface if it is integral with or bonded to that surface. As used herein, a layer is “directly bonded” to a surface if the layer is connected (e.g., adhered) to that surface. As used herein, a layer is “indirectly bonded” to a surface if the layer is connected to that surface via one or more intermediate layers (e.g., adhesives or primers).

In some embodiments, the surface-feature image-generating layer is integral with the first major surface of the substrate. For example, in some embodiments, the first major surface of the substrate may be embossed (e.g., flame embossed), engraved, etched, and/or ablated (e.g., laser ablated) to create surface features. In some embodiments, the material comprising the substrate may be cast against a patterned roll to create surface-features integral to the cast-surface of the substrate.

In some embodiments, the surface-feature image-generating layer comprises a layer (e.g., a resin layer) directly or indirectly bonded to the first major surface of the substrate. Exemplary resins include polymers such as polyolefins and acrylics. In some embodiments, the resin layer may be, e.g., embossed, engraved, etched, and or ablated to form surface features. In some embodiments, the resin layer may be cast against a patterned roll to create the surface features. The formation of the surface features in the resin layer may be created either before or after the resin layer is combined with the substrate.

In some embodiments, surface features may be formed by incorporating particulates (e.g., organic and/or inorganic particles including e.g., silica particles) in the substrate or resin layer. For example, in some embodiments, particulates may be embedded in the first surface of the substrate. In some embodiments, particulates may be applied to or incorporated in a resin layer applied to the surface of the substrate.

Generally, the surface-feature image-generating layer may be continuous or discontinuous. For example, only portions of the first major surface may be embossed or otherwise processed to create surface features. Similarly, in some embodiments, a resin layer, which may contain particulates, may be applied to only certain areas of the substrate. Alternatively, the resin layer itself may be continuous, but only certain regions may be embossed such that the surface features are discontinuous.

In some embodiments, the textured surface may comprise random or stochastic surface features that may result in, e.g., a matte appearance. In some embodiments, the surface features may be selected to achieve a desired surface-feature-generated image. For example, in some embodiments, geometrical structures such as pyramids, cones, cubes, hemispheres, and the like may be selected. In some embodiments, known techniques may be used to form an array of grooves resulting in, e.g., a hologram.

Combinations of random, stochastic, and designed surface features may be used. In some embodiments, the surface features are associated with substantially the entire first surface of the substrate. In some embodiments, surface features may be associated with only selected portions of the first surface, either randomly, or in a defined pattern, e.g., words, symbols, pictures, and the like.

Generally, the greater the difference in refractive index between the ambient environment and the textured layer, the greater the intensity of the resulting surface-feature-generated image. In most practical applications, the ambient environment is air, having a refractive index of about 1.0. Thus, to increase the intensity of the surface-feature-generated image, one would select a material for the textured layer having as high a refractive index as possible or practical, resulting in a large refractive index change at the interface between the textured layer and the air.

However, in order to detect tape-over, the refractive index of a textured layer of the present disclosure is selected to be comparable to the refractive index of common adhesives. Thus, if articles according to the present disclosure are taped over, the low refractive index air is replaced by the adhesive of the tape. If the refractive index of the textured layer is comparable to the refractive index of common adhesives, the refractive index change at the interface between the textured layer and the adhesive will be small. This decrease in the refractive index change that results from replacing air with an adhesive at the surface of the textured layer can result in a significant and easily detectable difference in the intensity of the surface-feature-generated image. Generally, this change in image intensity can allow for easy detection of tape-over, allowing the articles of the present disclosure to be used to detect tampering.

In some embodiments, tape-over detection may be enhanced by selecting a tamper-detecting article according to the present disclosure that has a width greater than that of typical tapes (e.g., box sealing tapes) that might be used for tape-over. In such embodiments, two or more pieces of tape would be required to tape-over the entire tampering indicating article, and the seams between the tapes may provide an additional indication of tampering. Alternatively, in some embodiments, if only a single piece of tape is used to tape-over, there will be a distinct transition in surface-feature-generated image intensity at the tape-over edge. A common width for box sealing tape is 48 mm (1.9 inches); thus, tapes having a width of at least 50 mm, e.g., 50 to 60 mm, may be useful. Other typical tapes are generally 5 to 8 centimeters (cm) (2 to 3 inches) wide; thus, in some embodiments, tamper indicting article widths of at least 8 cm, and in some embodiments, at least 10 cm may be useful.

In some embodiments, the refractive index of the textured layer falls within the range of plus or minus 0.2 of the refractive index of typical adhesives. Typical adhesive refractive indices range from about 1.4 to about 1.5. In some embodiments, the refractive index of the textured layer is at least about 1.25; in some embodiments, at least about 1.3; in some embodiments, at least about 1.35; or even at least about 1.4. In some embodiments, the refractive index of the image generating layer is no greater than about 1.7; in some embodiments, no greater than about 1.6; or even no greater than about 1.5.

As the selection of the specific tape that may be used for tape-over is unpredictable, in some embodiments, it may be desirable to select a textured layer having a refractive index close to the mid-point of the distribution of refractive indices for common adhesives. In some embodiments, the refractive index of the textured layer is between 1.4 and 1.5, inclusive; in some embodiments, between 1.42 and 1.5, inclusive; and in some embodiments, between 1.45 and 1.5, inclusive.

Generally, in order to increase the efficiency of tape-over detection, it is desirable to optimize the difference in image intensity between a surface-feature-generated image before and after tape-over. In order to accomplish this, one must balance a desire to increase the image intensity before tape-over, with the desire to minimize image intensity after tape-over.

As discussed above, selecting a material having the desired refractive index relative to air and the adhesives potentially used for tape-over plays a significant role in achieving the desired change in image intensity. However, the dimensional characteristics of the surface features also play a role.

In the case of both refractive and diffractive surface-feature-generated images, as the height of the surface features increases, the image intensity increases. In both cases, the minimum height is generally about one-quarter wavelength. In the case of visible light (i.e., light having a wavelength of 380-780 nanometers (nm)), this leads to minimum surface feature heights of about 90 to about 200 nm (i.e., about 0.09 to about 0.2 micrometers (μm)).

In some embodiments, diffractive images may be desired. Generally, the intensity of a diffractive image increases with feature height as the feature height is increased from one-quarter wavelength to one wavelength. In some embodiments, little or no additional diffractive image intensity is gained by increasing the height beyond one wavelength. In some embodiments, the feature height is no greater than 2 μm, or even no greater than 1 μm.

In some embodiments, refractive images may be desired. Generally, the intensity of a refractive image increases with feature height, even beyond heights of one wavelength. Thus, in some embodiments, it may be desirable to select feature heights of 10, 50, 100, 200, or even 400 times the wavelength of light. For light near the center of the visible spectrum, e.g., 600 nm, this would result in feature heights of about 6 μm, 30 μm, 60 μm, 120 μm, and 240 μm, respectively. However, as discussed below, increasing the feature height can create problems when trying to minimize the image intensity upon tape-over, and may be detrimental to the goal of optimizing the difference in image intensity before and after tape-over.

Generally, the surface features have a characteristic width (i.e., a characteristic dimension in the plane of the refractive image-generating layer typically perpendicular to the characteristic height of the feature). In some embodiments, the width of the features may be as small as one-quarter wavelength of light (i.e., as small as about 100 nm). However, in some embodiments, the width of the features is typically greater than the wavelength of light, i.e., greater than about 400 nm (i.e., 0.4 μm). In some embodiments, the width is at least about 0.5 μm, or even at least about 0.8 μm. Generally, the intensity of a surface-feature-generated image may be increased by decreasing the width relative to the height of the features. In some embodiments, the features have a width of no greater than 10 μm; in some embodiments, no greater than 5 μm; or even no greater than 2 μm.

In order to achieve tape-over detection, the air/textured surface interface is replaced with an adhesive/textured surface interface. By selecting a surface-feature image-generating layer having a refractive index comparable to that of common adhesives, the difference in refractive index at the interface will be reduced, thereby reducing the intensity of the associated surface-feature-generated image.

Several parameters affect the ability of the adhesive to displace air at a textured interface. For example, the height of the surface features should be less than the thickness of the adhesive layer. For stiffer adhesives (i.e., adhesives less likely to flow into the features), it may be desirable to limit the height of the surface features to less than half, or even less than one-quarter the thickness of the adhesive layer.

The adhesive layer on many common tapes is less than 50 μm, and may be less than 25 μm, or even less than 15 μm. Thus, in some embodiments, it may be desirable to include features having an average height of less than about 50 μm, less than about 25 μm, or even less than about 15 μm. In some embodiments, it may be desirable to limit the average feature height to less than about 5 μm, or less than about 2 μm, or even less than about 1 μm.

Due to, e.g., design considerations, manufacturing variability, and other known factors, it may be difficult or even undesirable to have each surface feature comply with desired heights and widths. In some embodiments, at least 75% of the surface features will have the desired height and/or width. In some embodiments, at least 85%; in some embodiments, at least 90%; and in some embodiments, at least 95% of the surface features will have the desired height and/or width.

Generally, the ability of a person to detect tape-over will depend on both the original image intensity (i.e., the image intensity before tape-over) and the change in image intensity (i.e., the relative decrease in image intensity upon tape-over).

Holograms are available having a high index of refraction coating applied to the textured surface, as this increases the difference in refractive index at the air interface, thus increasing the image intensity. However, the use of such high index of refraction coatings is contrary to the present desire to use a material having a refractive index comparable to common adhesives.

The present inventors have determined that the intensity of the original surface-feature-generated image can also be enhanced by locating a contrast layer beneath the surface-feature image-generating layer without disrupting the desired refractive index at the air interface.

Generally, any layer capable of providing increased contrast relative to the surface-feature-generated image may be used. The contrast layer may be continuous or discontinuous. Exemplary contrast layers include metals, metal oxides, metal sulfides, and combinations thereof. The contrast layer may also comprise a colored layer, e.g., a colored film or an ink. Generally, black provides a good contrast layer, although other colors, including dark colors, may be used. In some embodiments, dyes and/or pigments may be incorporated into the contrast layer.

In some embodiments, the contrast layer may be selected to increase image intensity under diffuse lighting conditions. In some embodiments, the contrast layer may be reflective, including, e.g., glossy layers (e.g., glossy inks). Alternatively, in some embodiments a retro-reflective contrast layer may be used. However, a retroreflective layer generally will not increase image intensity under diffuse lighting conditions. In such embodiments, a special light source may be required, making the article less suitable for convenient tamper detection.

In some embodiments, the image-generating surface-features may be fragile, e.g., susceptible to abrasion, scratching or other mechanical damage. It would be possible to bury fragile image-generating features by, e.g., placing the textured surface of the substrate against an adhesive layer or a contrast layer, so that the opposite, smooth surface of the substrate is exposed to the air. Also, optically thick abrasion resistant coatings have been applied using materials having a significant refractive from the underlying texture layer. However, such approaches would not allow tape-over detection as the image-generating features are no longer “surface” features.

The present inventors have determined that optically thin functional coatings (e.g., less than about one-quarter wavelength of light) can be applied to the exposed textured surface without substantially affecting the generation of surface-feature-generated images, and without adversely affecting tape-over detection. In some embodiments, two or more functional coatings may be applied. Because the physical presence of these coatings has little or no effect on the optical interface, i.e., the refractive index interface between the air and the textured surface, these functional coatings are considered to be associated with, and thus part of the surface-feature image-generating layer.

As used herein, “a coating” refers to a continuous or discontinuous layer present on the surface of an underlying layer regardless of the mean by which the coating was applied. For example, “a coating” may be applied by traditional coating methods (e.g., roll coating) or it may be applied by, e.g., spraying, laminating, extruding, and the like.

Exemplary surface coats include hard coats (i.e., abrasion resistant coatings), and coatings that provide water or chemical resistance. In some embodiments, an optically thin release coating may be applied to the textured surface. The presence of the release coating would allow the tape to be self wound (i.e., the adhesive on the backside of the substrate would come into contact with the release-coated textured surface of the top side of the substrate as the material is wound into a roll. Of course, in some embodiments, a separate release liner may be used to cover the adhesive layer, either with or without a separate release coating applied to the textured surface of the substrate.

The substrate may comprise any known material including known tape backings such as, e.g., polymeric films. Exemplary polymeric films include polyolefins (polypropylene and polyethylene), polyesters, acetates, vinyls, polyamides, and the like. If the surface-feature image-generating layer is integral with the substrate, factors affecting substrate selection may include refractive index and compatibility with the desired surface-feature creation method (e.g., embossing, casting, etching, and the like). These considerations may also affect selection if a resin is applied to a substrate, but in such embodiments, a broader range of underlying substrates may be useful.

In some embodiments, the substrate is transparent, i.e., the substrate transmits at least 30% of the visible light incident upon it. In some embodiments, a substrate will transmit at least 50%; in some embodiments, at least 60; in some embodiments, at least 75; and even at least 90% of the visible light incident upon it. In some embodiments, at least one, and in some embodiments all layers, associated with the first major surface of the substrate are transparent.

Generally, any known adhesive may be used. The adhesive may be, for example, a heat activatable adhesive, or a pressure sensitive adhesive.

Suitable pressure sensitive adhesive components can be any material that has pressure sensitive adhesive properties including the following: (1) permanent tack at room temperature (20° C. to 25° C.), (2) adherence to a substrate with no more than finger pressure, (3) sufficient ability to hold onto an adherend, and (4) sufficient cohesive strength to be removed from the adherend. Furthermore, the pressure sensitive adhesive component can be a single pressure sensitive adhesive or the pressure sensitive adhesive can be a combination of two or more pressure sensitive adhesives.

Pressure sensitive adhesives useful in the present invention include, for example, those based on natural rubbers, synthetic rubbers, styrene block copolymers, polyvinyl ethers, poly (meth)acrylates (including both acrylates and methacrylates), polyolefins, and silicones.

The pressure sensitive adhesive base material may be inherently tacky. If desired, tackifiers may be added to the base material to form the pressure sensitive adhesive. Useful tackifiers include, for example, rosin ester resins, aromatic hydrocarbon resins, aliphatic hydrocarbon resins, and terpene resins. Other materials can be added for special purposes, including, for example, oils, plasticizers, antioxidants, ultraviolet (“UV”) stabilizers, hydrogenated butyl rubber, pigments, and curing agents.

Generally, any known technique may be used to apply the adhesive to the substrate including, e.g., coating (e.g., roll coating), spraying, laminating, and the like. In addition, the adhesive layer may be extruded onto the substrate layer, or co-extruded with the substrate layer.

Single-image tamper-indicating articles.

Referring to FIGS. 1a and 1b, an exemplary single-image, tamper indicating article according to some embodiments of the present disclosure is shown. Tampering indicating article 10 comprises substrate 20 having a first major surface 22 and a second major surface 24. Adhesive 40 is directly bonded to second major surface 24. In some embodiments, a primer layer or other coating may be interposed between the adhesive layer and the second major surface of the substrate.

First major surface 22 comprises surface features 30. When viewed under the appropriate lighting conditions, visible image 50 is formed by the interaction of light with surface features 30; thus, visible image 50 is a surface-feature-generated image.

Referring to FIG. 1b, a cross-section of tampering indicating article 10 is shown. Surface features 30 are integral with first major surface 22 of substrate 20; thus the surface-feature image-generating layer of this embodiment comprises first major surface 22.

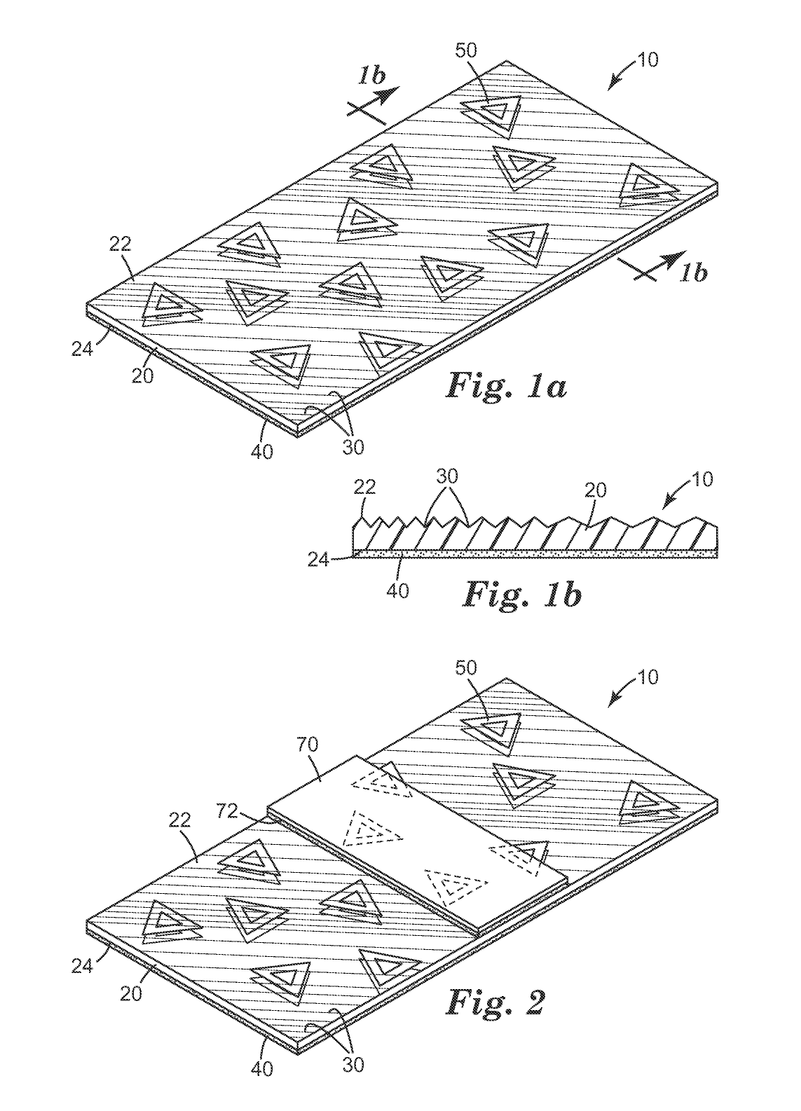

Referring to FIG. 2, common adhesive tape 70 has been applied to a first region of first major surface 22. Adhesive 72 has wet-out surface features 30 in this taped-over region replacing air at the interface. As a result, the intensity of visible image 50 is substantially reduced. For illustrative purposes, in the taped-over region, visible image 50 is shown in dashed-line format to indicate this substantial reduction in intensity. In some embodiments, visible image 50 is no longer perceptible in the taped-over region.

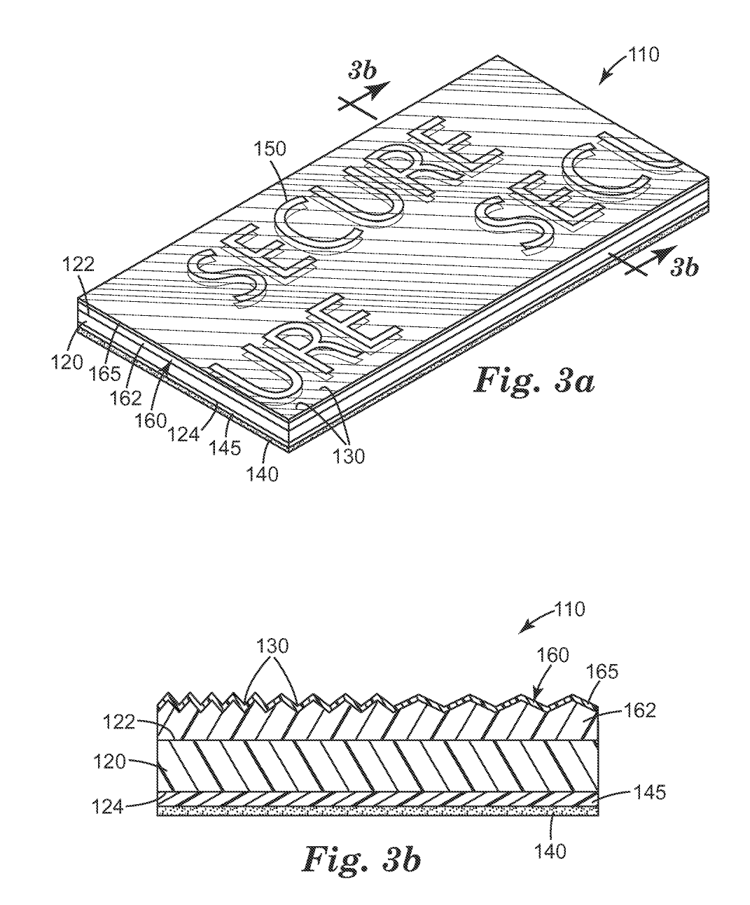

Referring to FIGS. 3a and 3b, another exemplary single-image tamper indicating article according to some embodiments of the present disclosure is shown. Tampering indicating article 110 comprises substrate 120 having a first major surface 122 and a second major surface 124. Adhesive 140 is indirectly bonded to second major surface 124 via primer layer 145.

Surface-feature image-generating layer 160 is associated with first major surface 122. Surface-feature image-generating layer 160, which comprises resin layer 162 and optional functional layer 165, has surface features 130, which when viewed under the appropriate lighting conditions, form visible image 150 by the interaction of light with surface features 130. Surface features 130 may be formed by any known means, including those discussed herein (e.g., embossing, etching, ablating, casting, and the like).

If an adhesive tape was applied to a portion of surface-feature image-generating layer 160, the adhesive would wet-out surface features 130 in that portion. This would result in a detectable reduction in the intensity of visible image 150 in that portion relative to the intensity of the visible image in the portions that were not taped over.

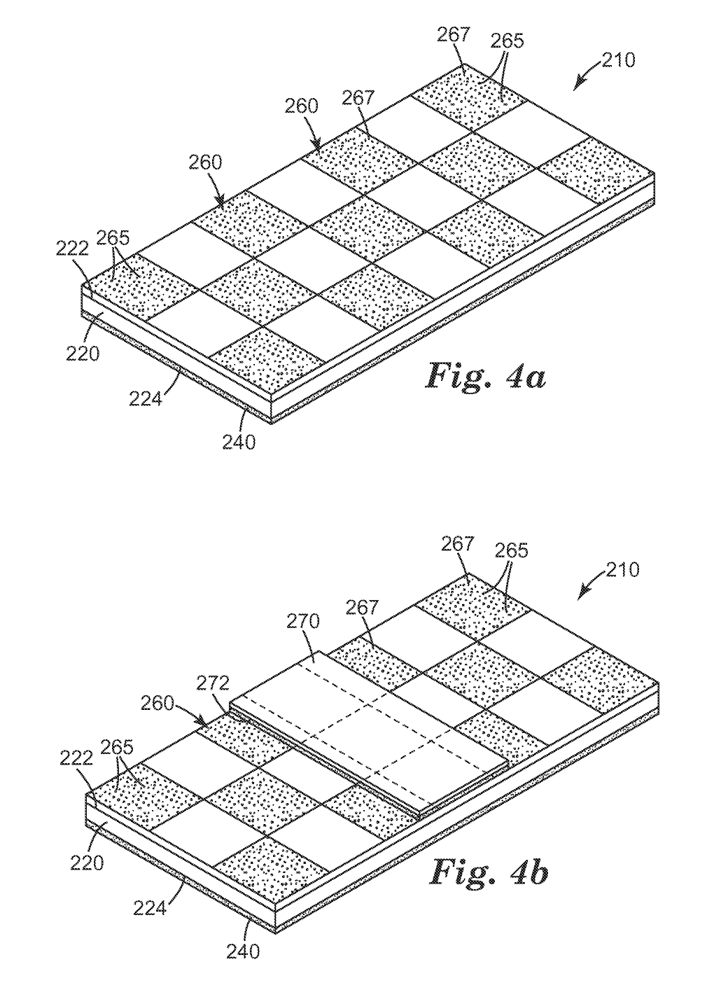

Referring to FIG. 4a, yet another exemplary single-image tamper indicating article according to some embodiments of the present disclosure is shown. Tampering indicating article 210 comprises substrate 220 having a first major surface 222 and a second major surface 224. Adhesive 240 is directly bonded to second major surface 224.

Surface-feature image-generating layer 260 is associated with first major surface 222. Surface-feature image-generating layer 260 comprises particles 265 and resin 267. When viewed under the appropriate lighting conditions, the interaction of light with surface features comprising particles 265 forms a visible image, i.e., a matte appearance, in the checkerboard regions comprising surface-feature image-generating layer 260.

Referring to FIG. 4b, common adhesive tape 270 has been applied to a first region of first major surface 222. Adhesive 272 has wet-out the surface features in this taped-over region replacing air at the interface. As a result, the intensity of the surface-feature-generated matte appearance is substantially reduced. For illustrative purposes, the checkerboard lines marking the boundaries between the matte-appearing regions of the tamper indicating article are shown as dashed lines in the taped-over region. Generally, the intensity of the surface-feature generated matte appearance is substantially reduced or even eliminated in the taped-over region.

Dual-image tamper indicating articles.

Generally, the ability to detect tape-over depends on the reduction in intensity of a surface-feature generated image when air is replaced with adhesive, i.e., a visible image tends to “disappear” when taped-over. In some embodiments, additional tape-over detection can be achieved by including a second image that “appears” upon tape-over. Generally, such a dual-image tamper indicating article can be achieved by combining a first surface-feature generated image with a second image. In some embodiments, the second image is a second surface-feature generated image adjacent the first surface-feature generated image. In some embodiments, the second image is buried by (i.e., obscured below) the first surface-feature generated image.

Buried, dual-feature tamper indicating articles.

Ideally, the relative intensities of the images would be such that the intensity of the first surface-feature generated image would obscure (i.e., minimize or prevent visible detection of) the second, underlying image prior to tape-over. Upon tape-over, the intensity of the surface-feature generated image would be reduced such that the second, underlying image would be visible.

Generally, any image produced by any known method may be used for the second, underlying image. For example, printed images (e.g., traditionally printed images (e.g., letterpress, flexographic, or screen printed images) or digitally printed images (e.g., ink jet or thermal transfer printing images) may be used. In some embodiments, the second, underlying image may comprise a hologram.

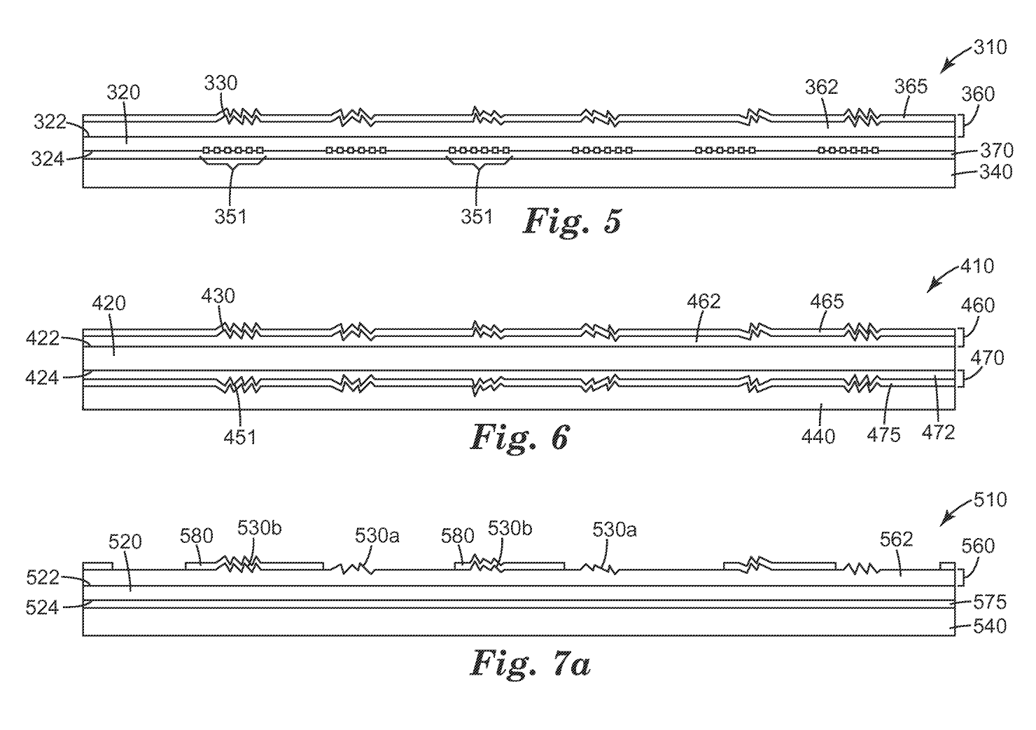

Referring to FIG. 5, an exemplary buried, dual-image tamper indicating article including a second, underlying image, according to some embodiments of the present disclosure is shown. Tampering indicating article 310 comprises first substrate 320 having a first major surface 322 and a second major surface 324. Surface-feature image-generating layer 360 is associated with first major surface 322. In some embodiments, the surface-feature image-generating layer may be formed directly in the first surface of the first substrate. In some embodiments, as shown, e.g., in FIG. 5, surface-feature image-generating layer 360 includes resin layer 362 and optional functional layer 365.

When viewed under the appropriate lighting conditions, surface features 330 form a visible image (i.e., a first surface-feature generated image) by the interaction of light with surface features 330. Surface features 330 may be formed by any known means, including those discussed herein (e.g., embossing, etching, ablating, casting, coating (e.g., particle-filled resins) and the like). Any surface-feature-generated visible image may be used, including, e.g., holograms. Although surface features 330 are shown as a pattern of grooves, the surface features may also be particulates in a resin, and the surface-feature-generated image may be a simple matte appearance.

Tamper indicating article 310 also includes buried image 351. In some embodiments, the buried image may not be detectable when viewed through the visible surface-feature-generated image. In some embodiments, the underlying image may be visible; however, generally the surface-feature generated image should be more intense than buried image 351 prior to tape-over.

Generally, buried image 351 may be located anywhere in the construction, provided it is positioned below (i.e., is visually obscured by) the surface-feature generated image. For example, in some embodiments the buried image may be located between the first major surface of the first substrate and the resin layer. In some embodiments, as shown in FIG. 5, buried image 351 may be associated with (e.g., integral with or bonded to), second major surface 324 of first substrate 320.

In some embodiments, a buried image may be associated with second substrate, positioned below the first substrate when viewed through the surface-feature image-generating layer. In some embodiments, the buried image may comprise an ink. In some embodiments, the buried image may comprise an opaque coating.

In some embodiments, this optional second substrate may be bonded directly to the second major surface of the first substrate. In some embodiments, the second substrate may be bonded indirectly to the second major surface of the first substrate, e.g., one or more bonding layers (e.g., adhesive layers and or primer layers) may be located between the second substrate and the second major surface of the first substrate.

In some embodiments, an adhesive layer may be located on the side of the first substrate opposite the surface-feature image generating layer. For example, an adhesive may be directly bonded to the second major surface of the first substrate. In some embodiments, as shown in FIG. 5, one or more additional layers, e.g., contrast layer 370, may be included between second major surface 324 of first substrate 320 and adhesive layer 340. Other optional intermediate layers include, e.g., primers. These and other optional layer may be positioned on top of the buried image, between the buried image and first substrate, and/or on either side of an optional second substrate. In some embodiments where a second substrate is used, an adhesive layer may be associated with a surface of the second substrate.

If an adhesive tape was applied to a portion of surface-feature image-generating layer 360, the adhesive would wet-out surface features 330 in that portion. This would result in a detectable reduction in the intensity of the surface-feature-generated visible image in that portion relative to the intensity of the visible image in the portions that were not taped over. This reduction in intensity would allow buried image 351 to become visible through surface-feature image-generating layer 360 in the taped-over portion. Thus, upon tape-over, not only would the surface-feature-generated image decrease in intensity (e.g., disappear) in the taped-over portion, but the underlying image would appear (become visible) in this region as well.

Referring to FIG. 6, a second exemplary buried, dual-image tamper indicating article according to some embodiments of the present disclosure is shown. Tampering indicating article 410 comprises first substrate 420 having a first major surface 422 and a second major surface 424. Surface-feature image-generating layer 460 is associated with first major surface 422. In some embodiments, the surface-feature image-generating layer may be formed directly in the first surface of the first substrate. In some embodiments, as shown, e.g., in FIG. 6, surface-feature image-generating layer 460 includes resin layer 462 and optional functional layer 465. Surface features 430, which when viewed under the appropriate lighting conditions, form a visible image by the interaction of light with surface features 430 (i.e., a first surface-feature-generated image). Surface features 430 may be formed by any known means, including those discussed herein (e.g., embossing, etching, ablating, casting, coatings (e.g., particle-filled resins) and the like). Any surface-feature-generated visible may be used, including, e.g., holograms and a matte appearance.

Tamper indicating article 410 further includes a second buried image resulting from the interaction of light with underlying features 451 of image-generating layer 470. In some embodiments, the underlying features may be integral with the second major surface of the first substrate. In some embodiments, the underlying features may be associated with a second substrate. In some embodiments, as shown in FIG. 6, underlying features 451 may be included with resin layer 472. In some embodiments, additional layers, e.g., contrast layer 475, may be used to enhance the intensity of the underlying image. In some embodiments, underlying image is a hologram. In some embodiments, the underlying image is a matte appearance. In some embodiments, tamper indicating article also includes an adhesive layer, e.g., adhesive layer 440.

If an adhesive tape was applied to a portion of surface-feature image-generating layer 460, the adhesive would wet-out surface features 430 in that portion. This would result in a detectable reduction in the intensity of the surface-feature-generated visible image in that portion relative to the intensity of the visible image in the portions that were not taped over. This reduction in intensity would allow the buried image resulting from the interaction of light with underlying features 451 of image-generating layer 470 to become visible through surface-feature image-generating layer 460 in the taped-over portion. Thus, upon tape-over, not only would the surface-feature-generated image decrease in intensity (e.g., disappear) in the taped-over portion, but the buried image would appear (i.e., become visible) in this region as well.

Adjacent, dual-image tamper indicating articles.

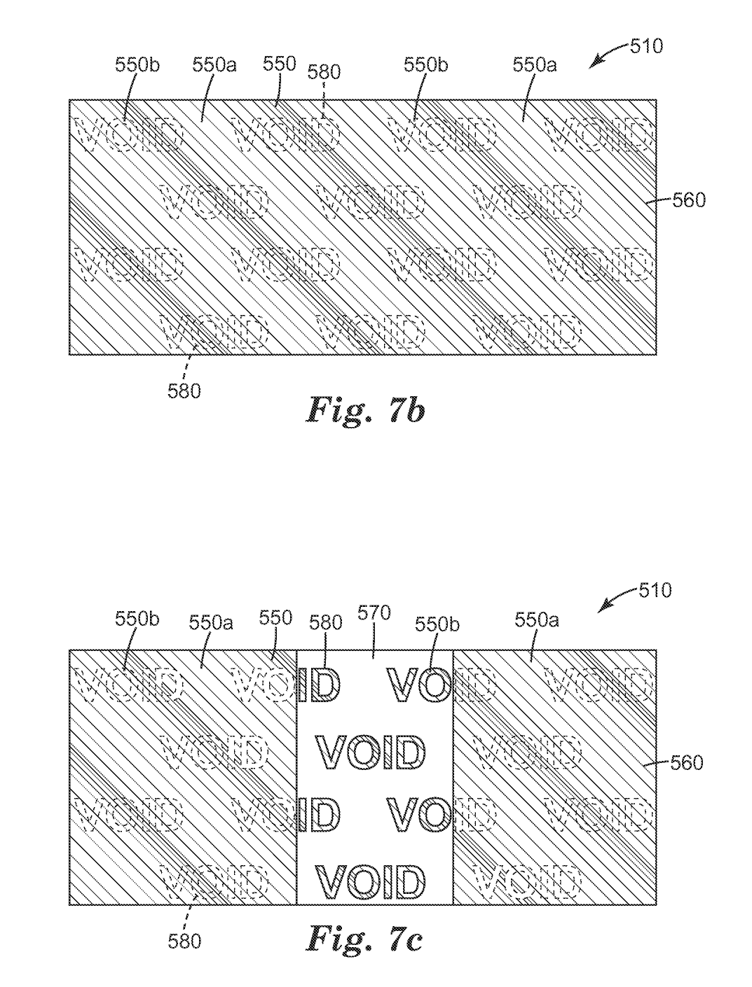

Referring to FIGS. 7a and 7b, an adjacent, dual-image tamper indicating article according to some embodiments of another aspect of the present disclosure is shown. Tampering indicating article 510 comprises first substrate 520 having a first major surface 522 and a second major surface 524. Surface-feature image-generating layer 560 is associated with first major surface 522. In some embodiments, the surface-feature image-generating layer may be formed directly in the first surface of the first substrate. In some embodiments, as shown, e.g., in FIG. 7a, surface-feature image-generating layer 560 includes resin layer 562 and any optional functional layers (not shown).

Tampering indicating article 510 also includes refractive index modifying layer 580 and optional contrast layer 575. As shown, optional contrast layer 575 is positioned between second surface 524 and optional adhesive layer 540, although the contrast layer may be included in other locations as well (e.g., between first surface 522 and resin layer 562). One or more additional layers, e.g., primer layers, may also be included.

Refractive index modifying layer 580 is applied to cover some surface features (e.g., surface features 530b), leaving other surface features (e.g., surface features 530a) uncovered. Refractive index modifying layer 580 may be applied randomly or stochastically. In some embodiments, refractive index modifying layer 580 may be applied to create a recognizable image or pattern, e.g., numbers and/or letters.

The first surface-feature generated image is comprised of those surface features 530b that are covered by refractive index modifying layer 580. The second surface-feature generated image is comprised of those surface features 530a that are not covered by refractive index modifying layer 580. Unlike the buried, dual-feature tamper indicating articles, the second surface-feature generated image is not buried beneath the first surface feature generated layer. Rather, the first surface-feature generated image is adjacent the second surface-feature generated layer.

Referring to FIG. 7b, when viewed under the appropriate lighting conditions, surface features 530 form visible image 550 by the interaction of light with surface features 530 (i.e., a surface-feature generated image). The surface features may be formed by any known means, including those discussed herein. Any surface-feature-generated visible image may be used, including, e.g., holograms and a matte appearance. For simplicity, surface-featured-generated visible image 550 is depicted as closely-spaced lines.

In the embodiment of FIGS. 7a and 7b, a single common image is used over the entire surface of tamper indicating article. First surface-feature-generated image 550a corresponds to the portion of this common image in the uncovered regions, while second surface-feature-generated image 550b corresponds to the portions of this common image that are covered by refractive index modifying layer 580. For illustrative purposes, the covered regions corresponding to second surface-feature-generated image 550b is shown by dashed lines spelling the word “VOID.” However, generally, prior to tape-over, a uniform surface-feature-generated (e.g., holographic) appearance corresponding to the visible images generated by surface features 530, including surface features 530a and 530b, is visible.

Referring to FIG. 7c, with the appropriate selection of the refractive indices of refractive index modifying layer 580 and surface-feature image-generating layer 560 relative to common tapes used for tape-over, upon tape-over, the relative intensities of second surface-feature-generated image 550b generated by surface features 530b covered by refractive index modifying layer 580 and first surface-feature-generated image 550a generated by surface features 530a that were not covered will differ.

In some embodiments, the refractive index of surface-feature image-generating layer may be selected to match the refractive index of common adhesives, while the refractive index of the refractive index modifying layer is selected to differ from the refractive index of common adhesives. In such embodiments, when tape over occurs, the image created by the surface features uncovered by the refractive index modifying layer will diminish in intensity, while the intensity of the image created by the surface features covered by the refractive index modifying layer will be less affected or even unaffected.

This embodiment is illustrated in FIG. 7c. As shown, this results in a visible and easily detected contrast between the lower intensity first surface-feature-generated image, 550a, and the adjacent, higher intensity, second surface-feature-generated image, 550b in the taped-over portion 570. As shown, there is little or no detectable difference in intensity between the adjacent images in portion that has not been taped-over.

In some embodiments, the refractive index of the surface-feature image-generating layer may not match the refractive index of common adhesives, e.g., the substrate may be selected for other performance criteria. In such embodiments, the refractive index of the refractive index modifying layer may be selected to match the refractive index of common adhesives. In such embodiments, when tape over occurs, the image created by the surface features covered by the refractive index modifying layer, i.e., second surface-feature-generated image 550b, will diminish in intensity, while the intensity of the image created by the surface features uncovered by the refractive index modifying layer, i.e., first surface-feature-generated image 550a, will be less affected or even unaffected.

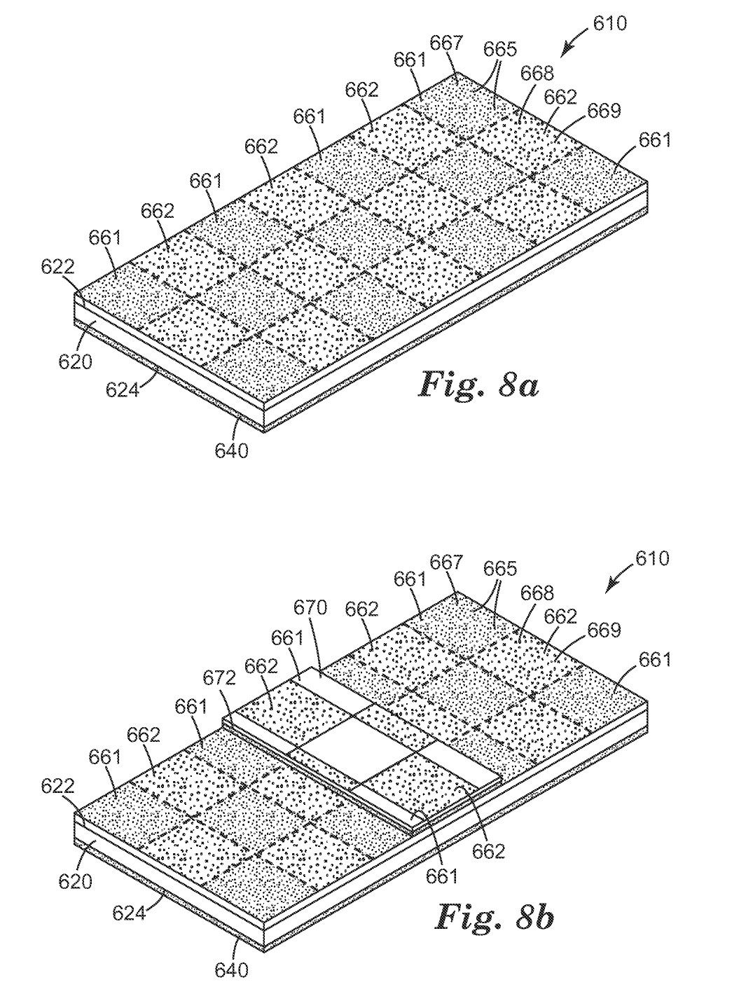

Referring to FIG. 8a, another exemplary embodiment of an adjacent, dual-image tamper indicating article is shown. Tamper indicating article 610 comprises substrate 620 having a first major surface 622 and a second major surface 624. Adhesive layer 640 may be associated with second major surface 624.

First surface-feature image-generating layer 661 is associated with a first portion of first major surface 622. Second surface-feature image-generating layer 662 is associated with a second portion of first major surface 622. First surface-feature image-generating layer 661 comprises first particles 665 and first resin 667. Second surface-feature image-generating layer 662 comprises second particles 668 and second resin 669.

Generally, the first resin and the second resin may be independently selected and may be the same or different resins. Also, the compositions and sizes of first particles 665 and second particles 668 may be independently selected, and may be the same or different. When viewed under the appropriate lighting conditions, the interaction of light with the first surface-feature image-generating layer 661 generates a first surface-featured generated image. Similarly, the when viewed under the appropriate lighting conditions, the interaction of light with the second surface-feature image-generating layer 662 generates a second surface-featured generated image. Generally, prior to tape over, the overall appearance of first major surface 622 will appear substantially uniform, e.g., a uniform matte appearance.

Referring to FIG. 8b, common adhesive tape 670 has been applied to a first region of first major surface 622. Adhesive 672 has wet-out only first surface-feature generating layer 661, replacing air at the interface. As a result, the intensity of the first surface-feature-generated matte appearance is substantially reduced. As second surface-feature image-generating layer 662 is less wet out (e.g., not wet out) by adhesive 672, the intensity of the second surface-feature generated image is greater than the diminished intensity of the first surface-feature generated image. As a result, the second surface-feature generated image “appears” when tape-over occurs.

Numerous means are available to create differential wet-out between first surface-feature generating layer 661 and second surface-feature image-generating layer 662. For example, the compositions of the respective resins and or particles may be adjusted relative to the expected surface tension of the adhesive, resulting in differential wet-out.

In addition, or alternatively, generally, smaller surface features are easier to wet-out than larger surface features. Also, the size of the surface features may be controlled by selection of the size of the particles present in the resin. Therefore, by selecting the sizes of the first particles and the second particles, the relative sizes of the surface features, and thus, the relative wet-out of the first surface-feature image generating layer and the second surface-feature generating layer may be adjusted.

In addition to these methods, the refractive indices of the particles and/or the resins may be selected such that the refractive index of only one of the first surface-feature generating layer 661 or second surface-feature image-generating layer 662 matches the refractive index of common adhesives. Thus, upon tape-over, only the surface-feature-generated image having a matched refractive index will reduce in intensity (e.g., disappear) leaving the intensity of the surface-feature-generated image having an unmatched refractive index unaffected or less affected.

Generally, each of these techniques for adjusting the relative wet-out and or refractive index matching may be used alone, or in combination with each other.

Controlled wet-out and/or refractive index matching may also be used with other surface-feature generated images. For example, in some embodiments, a uniform-appearing surface-feature generated hologram may be present on the first major surface of a tamper indicating article. Portions of the surface features may be treated to affect wet-out, e.g., application of a surface-tension modifying coating or treatment (e.g., irradiation). Alternatively, or additionally, the surface features may vary in dimensions (e.g., depth and width). As a result, adhesive wet-out may be adjusted between different portions of the surface features, causing a second surface-feature image (i.e., the less wet-out image) to “appear” when the adjacent first surface-feature generated image (i.e., the more wet-out image) disappears when the adhesive is applied.

### EXAMPLES

Various single-image tampering indicating articles were constructed. Each tamper indicating construction possessed surface features resulting in surface-feature-generated images (e.g., diffractive images (e.g., holograms) or refractive images (e.g., matte appearances)) that were visible to the unaided human eye. For each example, a selected transparent or translucent commercially available adhesive tape was applied to the exposed surface of the construction and rubbed down with a bare finger in an attempt to achieve complete wet-out of the adhesive onto the textured surface of the tamper indicating article.

The films used to evaluate tape-over detection are summarized in Table 1.

TABLE 1
Films having a surface-feature image-generating layer.

| | Material | |
|---|---|---|
| I.D. | Type | Film Description |
| A | Holographic | Polyester base film with an embossed resin layer |
| | Film | Part # OPT-100N-16Z, from Crown Roll Leaf, Inc., |
| | | Paterson, New Jersey |
| B | Holographic | Polyester base film with an embossed resin layer |
| | Film | Part # ONT-100N-707, from Crown Roll Leaf, Inc., |
| | | Paterson, New Jersey |
| C | Holographic | Polypropylene base film with an embossed resin |
| | Film | layer with a zinc sulfide high-refractive-index |
| | | coating on the exposed surface |
| | | Part # XPT-101S-AAZ, from Crown Roll Leaf, Inc., |
| | | Paterson, New Jersey |
| D | Matte Film | Bi-axially oriented polypropylene film, coated on |
| | | the underside with black glossy ink (HMC-80071 |
| | | from XSYS Print Solutions of Minneapolis, |
| | | Minnesota) using a 330 line, 3.47 BCM gravure |
| | | cylinder. Various matte finishes were applied to |
| | | the topside. |

The intensity of the surface-feature-generated image was qualitatively evaluated before tape-over. This assessment was made indoors under fluorescent lighting conditions. All samples were evaluated over a range of viewing angles and assigned a value of “excellent” or “very good.” The change in intensity of the surface-feature-generated image was qualitatively evaluated after tape-over, and a value of “complete” was assigned if the surface-feature-generated image was undetectable, a value of “slight reduction” was assigned if only a minimal change in image intensity was observed, and a value of “no reduction” was assigned if no change in image intensity was perceived. Finally, each sample was assigned a tape-over detection value of “excellent,” “very good,” or “poor” depending on both the initial image intensity and the qualitative difference in image intensity after tape-over.

### Example 1

A 10×15 cm (4×6 inch) piece of Film A was placed onto a corrugated cardboard surface, embossed side facing up. The surface-feature-generated image (i.e., the hologram) was visible but not intense. A 5×5 cm (2×2 inch) piece of box sealing tape (Product No. 355 from 3M Company (St. Paul, Minn.)) was adhered to the textured side of the film. The surface-feature-generated image was not perceptible in the taped-over region.

### Example 2

A glossy black surface was prepared by printing a solid black patch onto a piece of white polyester label stock (Product No 7331 from 3M Company) using a Zebra Thermal Transfer Printer and a Ricoh B110A black ribbon. A 4×10 cm (1.5×4 inch) piece of Film A was adhered to this glossy black surface using an adhesive transfer tape (product No. 9442 from 3M Company) so that the textured side of the film was facing up. The glossy black surface significantly increased the intensity of the surface-feature-generated image. A 2.5×7.5 cm (1×3 inch) piece of “MAGIC TAPE” from 3M Company was adhered to the textured side of the film. The surface-feature generated image (i.e., the hologram) was not perceptible in the taped-over region.

### Example 3

A 4×10 cm (1.5×4 inch) piece of Film A was adhered to a piece of aluminum foil tape (Product No. 425 from 3M Company) using adhesive transfer tape (Product No. 9442 from 3M Company) so that the textured surface was facing up. The reflective surface of the aluminum foil tape significantly enhanced the intensity of the surface-feature-generated image (i.e., the hologram). A 2.5×7.5 cm (1×3 inch) piece of “MAGIC TAPE” from 3M Company was adhered to the embossed side of the film. The surface-feature-generated image was not perceptible in the taped-over region.

### Example 4

The textured side of a 30 cm (12 inch) wide roll of Film B was coated with an optically thin (i.e., less than one-quarter wavelength of visible light) layer of C₃F₈ via a plasma deposition process. This low-surface energy coating had no noticeable effect on the intensity of the underlying surface-feature-generated image (i.e., the holographic image).

Next, an optically thick layer of aluminum (greater than 0.1 μm) was vapor deposited onto the backside of the film. The presence of the aluminum layer increased the intensity of the surface-feature-generated image; however, the surface-feature-generated images associated with Film B were less intense than those associated with Film A. This difference in pre-tape-over intensity may be related to differences in the spatial characteristics of the surface features, i.e., width, Rt, and Rq.

Next, a water-based acrylic pressure sensitive adhesive formulation (ROBOND PS-90 from Rohm and Haas Company, Philadelphia, Pa.) was coated over the aluminum layer and dried. This finished tape construction was wound into a roll with no release liner, i.e., in roll form, the adhesive was in direct contact with the C₃F₈ release coating on the textured surface. The roll could be unwound without blocking or adhesive transfer to the textured surface.

Finally, a 5×5 cm (2×2 inch) piece box sealing tape (Product No. 355 from 3M Company) was adhered to the textured side of the tape. The surface-feature-generated image was not perceptible in the taped-over region.

### Example 5

The textured side of a 30 cm (12 inch) wide roll of Film B was coated with an optically thin (i.e., less than one-quarter wavelength of visible light) layer of SiO₂ via a sputtering process to produce a hard-coat. This hard-coat was then over-coated with an optically thin layer of C₃F₈ via a plasma deposition process. Neither coating had any perceptible affect on the intensity of the underlying surface-feature-generated image. An optically thick layer of aluminum was vapor deposited onto the backside of the film. This reflective layer increased the intensity of the surface-feature-generated image.

Next, a water-based acrylic pressure sensitive adhesive formulation (ROBOND PS-90 from Rohm and Haas Company) was coated over the aluminum layer and dried. This finished tape construction was wound onto a roll with no release liner, and could be unwound without blocking or adhesive transfer.

Finally, a 5×5 cm (2×2 inch) piece of box sealing tape (Product No. 355 from 3M Company) was adhered to the textured side of the tape. The surface-feature-generated image was not perceptible in the taped-over region.

### Comparative Example CE-1

A 10×15 cm (4×6 inch) sample was cut from Film C. The high refractive index zinc sulfide coating on the textured surface made the film appear somewhat yellowish-brown in color. A 5×5 cm (2×2 inch) piece of box sealing tape (Product No. 355 from 3M Company) was adhered to each side of Film B. Due to the high difference between the refractive index of the box sealing tape adhesive and the zinc sulfide coating, neither piece of tape had any perceptible affect on the intensity of the surface-feature-generated image.

### Example 6

Three grams (g) of a low surface energy lacquer in the form of a water-based latex was blended with 1.9 g of a slurry of 0.25 μm diameter, cross-linked poly-methyl methacrylate microspheres in water. This blend was diluted with 12.5 g of deionized water. The microspheres accounted for 67% of the total solids in the resulting diluted solution. The diluted solution was coated onto a 40 μm (0.0016 inch) thick corona treated polyester film using a #3 Meyer Rod and dried for five minutes in an oven at 120° F. The resulting coating imparted a surface-feature-generated matte image to the polyester film.

A 5×5 cm (2×2 inch) piece of box sealing tape (Product No. 355 from 3M Company) was adhered to the textured side of the tape. The surface-feature generated image was not perceptible in the taped-over region.

### Example 7

About 0.8 kilograms (kg) (1.7 pounds) of a low surface energy lacquer in the form of a water-based latex was blended with about 0.45 kg (1.0 pounds) of a slurry of 0.25 μm diameter, cross-linked poly-methyl methacrylate microspheres in water. This blend was diluted with about 1.6 kg (3.55 pounds) of deionized water forming Solution 1. About 1.5 kg (3.31 pounds) of the low surface energy lacquer in the form of a water-based latex was diluted with about 1.2 kg (2.60 pounds) of deionized water to form Solution 2.

Solution 2 was uniformly applied onto the top surface of Film D using a 400 line, 3.80 BCM gravure cylinder. Next, diagonal stripes of Solution 1 were coated onto the uniform Solution 2 coating. The stripes were approximately 0.6 cm (0.25 inches) wide and there was a spacing of about 0.6 cm (0.25 inches) between each stripe. Both of these coatings were applied using a Mark Andy 4150 narrow web press at a web speed of about 27 meters per minute (90 feet per minute).

The stripes of Solution 1 were clearly visible as milky white matte surface-feature-generated images. The glossy black ink on the underside of the film enhanced the intensity of the surface-feature-generated matte appearing stripes of Solution 1. Next, a 5×15 cm (2×6 inch) piece of tape (Product No. 375 from 3M Company) was applied onto the coated top surface. The stripes of Solution 1 were not perceptible in the taped-over region.

### Comparative Example CE-2

A commercially-available matte-appearing tape (Product No. 821 from 3M Company) was applied to the topside of Film D. The tape was laminated carefully with a handheld rubber roller to avoid entrapping air. A second piece of tape (product No. 375 from 3M Company) was applied over the matte tape. The intensity of the surface-feature-generated image of the first matte tape was only slightly diminished in the taped-over region.

### Comparative Example CE-3

A second commercially-available matte-appearing tape (Product No. 471 Clear from 3M Company) was applied to the topside of Film D. The surface-feature-generated matte appearance of this tape was significantly less than the matter appearance of tape of CE-2. The second matte tape was laminated carefully with a handheld rubber roller to avoid entrapping air. A second piece of tape (product No. 375 from 3M Company) was adhered over the matte tape. The intensity of the surface-feature-generated matte image of the second matte tape was only slightly diminished in the taped-over region.

### Comparative Example CE-4

A piece of a third commercially-available matte-appearing tape (“CVS Invisible Tape”) was applied to the topside of Film D. The matte tape was laminated carefully with a handheld rubber roller to avoid entrapping air. A second piece of tape (Product No. 3M 375 from 3M Company) was taped over the matte tape. The intensity of the surface-feature-generated matte appearance of the third matte tape was only slightly diminished in the taped-over region.

The characteristic heights and widths of the various surface features were measured. Due to differences in the scales of the diffractive image generating features compared to the refractive image generating features, two different methods were used.

Holographic surfaces were profiled using Tapping Mode Atomic Force Microscopy (AFM). The instruments used for this analysis were a Digital Instruments Dimension 5000 Scanning Probe Microscope (SPM) System and a Dimension 3100 SPM System (both obtained from Veeco Instruments, Woodbury, N.Y.). The probes used were Olympus OTESPA single crystal silicon levers with a force constant of about forty Newtons per meter. The data were analyzed using Vision 3.44 software. For each sample, at least five 10×10 micrometer regions were measured. For each region, Rt (vertical distance from highest to lowest points) and Rq (root mean square average of the surface height measured relative to the mean plane within the evaluation area) were measured and recorded. The widths of the grooves of the holographic surface were measured directly in each region.

The surface features of the various matte surfaces were measured with a WYKO Optical Profiler (Veeco Instruments, Woodbury, N.Y.). Two scans taken in a single 0.5 by 0.5 mm region yielding estimates of Rt and Rq. The in-plane feature size range was estimated visually from a topographic map of the region that was generated by the optical profiler.

Characteristics of the surface features of the materials used for Examples 1-7, and Comparative Examples CE-1 through CE-4 are shown in Table 2.

The qualitative evaluations of the pre-tape-over intensity of the surface-feature-generated images, the change in image intensity upon tape-over, and an assessment of tape-over detection are summarized in Table 3.

TABLE 2
Surface feature characteristics.

| | | Surface-feature- | | | | | |
|---|---|---|---|---|---|---|---|
| Ex. # | Film | generated image | Width | | Rt(max) | Rq(max) | |
| 1-3 | OPT-100R-16Z | hologram | 1.2-1.6 | μm | 0.380 μm | 99.72 | nm |
| 4-5 | ONT-100R-707 | hologram | 0.8-1.2 | μm | 0.098 μm | 36.64 | nm |
| CE-1 | XPT-100S-AAZ | hologram | Not | | — | — | |
| | | | Measured | | | | |
| 6-7 | “Matte Lacquer” | matte | <5 | μm | 0.89 μm | 0.17 | μm |
| CE-2 | 3M #821 Tape | matte | 10-60 | μm | 6.37 μm | 1.65 | μm |
| CE-3 | 3M #471 Tape | matte | 20-150 | μm | 3.59 μm | 0.96 | μm |
| CE-4 | CVS Invisible | matte | 20-40 | μm | 6.06 μm | 1.19 | μm |

TABLE 3
Qualitative evaluations of Examples 1-7 and CE 1-4.

Surface-Feature-Generated
Image Intensity

| | Initial | Reduction after | Tape-over |
|---|---|---|---|
| Example | (pre-tape-over) | tape-over | Detection |
| 1 | Excellent | Complete | Excellent |
| 2 | Excellent | Complete | Excellent |
| 3 | Excellent | Complete | Excellent |
| 4 | Very good | Complete | Very good |
| 5 | Very good | Complete | Very good |
| CE-1 | Very good | No reduction | Poor |
| 6 | Very good | Complete | Very good |
| 7 | Very good | Complete | Very good |
| CE-2 | Very good | Slight reduction | Poor |
| CE-3 | Very good | Slight reduction | Poor |
| CE-4 | Very good | Slight reduction | Poor |

A 15×15 cm (6×6 inch) piece of 3M Retroreflective Labelstock #3929 was placed on a tabletop so that the retroreflective surface was facing up. The retroreflective surface provided a silvery, matte appearance and was not overtly reflective. For comparison, a 15×15 cm (6×6 inch) piece of 51 μm (0.002 inch) thick polyester film metallized with an optically thick coating of titanium was placed next to the retroreflective material. The optically thick titanium coating provided a bright reflective surface.

A 5×30 cm (2×12 inch) piece of Film A was placed across both the retroreflective film and the metallized film so that the holographic surface was facing up. The holographic film was then examined under normal office lighting conditions. The intensity of the surface-feature-generated holographic image was substantially enhanced by the presence of the metallized film, demonstrating its suitability as a contrast layer for use in diffuse (e.g., office and daylight lighting conditions). In contrast, the intensity of the surface-feature-generated holographic image was reduced by the presence of the retroreflective surface of the #3929 material, resulting in a dull and washed out appearance. In addition, the intensity of the image varied with the viewing angle. Thus, although a retroreflective contrast layer may be suitable for some applications, it is less preferable for diffuse lighting applications.

### Example 8

Example 8 illustrates the effectiveness on an alternative means of generated a surface-feature generated matte appearance, i.e., abrasion. A 15 cm by 15 cm sample of 125 micron thick PET film was obtained. The following optical properties of the film were measured: 90.4% Transmission, 99.7% Clarity, and 1.29% Haze. This film sample was then abraded by hand with 400 grit “WETORDRY Tri-M-ite” abrasive (available from 3M Company) until a uniform-to-the-eye matte surface appearance was achieved. The following optical properties of an abraded area of the film were measured: 90.4% Transmission, 66.5% Clarity, and 51.9% Haze. A 5 cm wide sample of #311 Box Sealing Tape (available from 3M Company) was then applied to the abraded area of the PET film. The following optical properties of the now taped-over abraded area were measured and optical readings measured: 91.9% Transmission, 97.8% Clarity and 4.9% Haze. Thus, optical measurements demonstrate that taping over an abraded surface is capable of significantly decreasing the intensity of the surface-feature generated image resulting from the abrasion of a film.

The following examples illustrate several exemplary embodiments of dual-image tamper indicating articles that include a second image buried beneath a first, surface-feature generated image.

### Example 9a

The cross-section of the tampering indicating article 410 illustrated in FIG. 6, is similar to the construction of Example 9a, wherein the buried image is a hologram and the surface-feature-generated image is a matte appearance resulting from the interaction of light with a particulate-containing coating.

A holographic film identified as ONT-100R-16Z was obtained from Crown Roll Leaf, Inc. The holographic film included 50 μm (2 mil) thick polyester substrate. As supplied, the topside of the holographic film included surface features (i.e., diffraction gratings) coated with an optically thick vapor coating of aluminum.

A 20 g batch of a low adhesion backsize (LAB) formulation was prepared by mixing 12.8 g of isopropanol (IPA); 4.43 g of silicone-polyurea release agent (20% Silicone (3M ID# 41-4202-3679-0, 15% in IPA)), and 2.75 g Chemisnow MR-2G (PMMA Microspheres, 33% in IPA). The LAB formulation was coated onto the backside of the holographic film with a number 4 Meyer Rod forming an LAB layer. The LAB layer had a surface-feature generated image, which provided a matte appearance.

An adhesive transfer tape (#9442 available from 3M Company) was laminated to the topside of the holographic film, directly onto the vapor coated holographic images. The resulting tamper indicating article thus comprised a polyester substrate having a surface-feature generating layer (i.e., the microsphere-containing LAB) on one surface forming a surface-feature-generated matte appearance. The diffraction gratings coated with an optical think layer of aluminum generated a second, holographic image, which was buried below the surface-feature-generated image (i.e., the matte appearance), completing this exemplary, buried, dual-feature tamper indicating article.

A 5 cm by 30 cm (3 inch by 12 inch) strip of the tamper indicating tape was adhered to a piece of corrugated cardboard. The buried holographic image was partially obscured by the matte appearance of the surface-feature generated image. Also, the surface-feature generated image disrupted the color-shifting property of the holographic buried image. A 5 cm by 7.5 cm (2 inch by 3 inch) piece of 3M #311 box sealing tape was applied to the matte appearing LAB layer. As the adhesive of the box sealing tape gradually wet out onto the construction, the matte appearance disappeared. As a result, the buried holographic image became readily visible and the color shifting property returned.

### Example 9b

Example 9a was repeated except that a 5 cm by 7.5 cm (2 inch by 3 inch) piece of 3M #371 box sealing tape was applied to the matte appearing LAB layer. Again, as the adhesive of the box sealing tape gradually wet out onto the construction, and the surface-feature-generated matte appearance disappeared. As a result, the holograms of the buried image became readily visible and the color shifting property returned.

### Example 10a

Examples 10a and 10b are similar to Examples 9a and 9b, but include a gold contrast layer.

A holographic film identified as XPT-101S-AAZ was obtained from Crown Roll Leaf, Inc. The holographic film included a 50 μm (2 mil) thick oriented polypropylene substrate. As supplied, the topside of the holographic film contained diffraction gratings generating a holographic image and included a high refractive index (HRI) layer.

A glass microsphere-containing LAB formulation was prepared as described in Example 9a. The LAB formulation was coated onto the backside of substrate with a number 4 Meyer Rod forming an LAB layer. The LAB layer had surface-features resulting in a surface-feature-generated image, which provided a matte appearance. Optically Clear Adhesive Transfer Tape (#8141, available from 3M Company) was laminated onto the topside of the holographic film, directly onto the HRI layer.

A 5 cm by 30 cm (3 inch by 12 inch) strip of this construction was cut and the release liner was removed leaving an optically clear adhesive layer. This strip was then laminated to the facestock of a 5 cm by 30 cm (3 inch by 12 inch) strip of Gold Tinted Metallic Label stock #7867 (available from 3M Company). The label stock also included an adhesive layer, which is protected by release liner.

The resulting buried, dual-image tamper indicating article included a surface-feature-generated image (i.e., the matte appearance) and a buried, holographic image. The construction also included a gold contrast layer positioned below the holographic image.

A 5 cm by 30 cm (3 inch by 12 inch) strip of this tamper indicating tape was adhered to a piece of corrugated cardboard. As with Example 9a, the buried holographic image was partially obscured and its color-shifting property was disrupted of the by the matte appearance of the surface-feature generated image. A 5 cm by 7.5 cm (2 inch by 3 inch) piece of 3M #311 box sealing tape was applied to the matte appearing LAB layer. As the adhesive of the box sealing tape gradually wet out onto the construction, the matte appearance disappeared. As a result, the holograms of the buried image became readily visible and the color shifting property returned.

### Example 10b

Example 10a was repeated except that a 5 cm by 7.5 cm (2 inch by 3 inch) piece of 3M #371 box sealing tape was applied to the matte appearing LAB layer. Again, as the adhesive of the box sealing tape gradually wet out onto the construction, the matte appearance disappeared. As a result, the holograms of the buried image became readily visible and the color shifting property returned.

### Examples 11-19

Examples 11-18 used strips of #7873 label stock (aluminum vapor-coated label stock having a mirror-like appearance, available from 3M Company) for a base substrate. For Example 19, the base substrate was a strip of #7819 label stock (vapor-coated label stock having a matte platinum appearance, available from 3M Co.).

Thermal transfer ribbons of various colors and gloss levels were selected and used to put a printed message onto the vapor coated surface of the base substrate to form the buried (i.e., second) image. A piece of holographic polyester film (ID# OPT-000N-16Z from Crown Roll Leaf) was then placed on top of the printed surface of the base substrate to determine how well the hologram masked the printing. The result was a buried, dual-image tamper indicating article similar to that depicted in FIG. 5. The results are summarized in Table 4.

TABLE 4
Qualitative evaluations of Examples 11-19.

| # | Ribbon | Description | Comments |
|---|---|---|---|
| 11 | Toppan RP | Black | Not good - Black ink image was clearly visible |
| | | | prior to tape-over |
| 12 | Coding Prods. | White | Fair - White ink image was somewhat visible |
| | TTR51YL | | prior to tape-over |
| 13 | DNP VW101 | Gold | Very Good - Ink image was masked well by the |
| | Gold | Metallic | hologram; however, the intensity of the ink image |
| | | | after tape-over was fair |
| 14 | Source and product | Silver | Very Good - Ink image was masked well by the |
| | I.D. unknown | Metallic | hologram; intensity after tape-over was fair |
| 15 | Coding Products | Yellow | Good - Yellow color did not match quite as well |
| | Product I.D. | | as the #7350 below and the resulting yellow ink |
| | unknown. | | image was somewhat visible prior to tape-over. |
| 16 | Coding Products | Yellow | Best - This yellow color matched well with the |
| | 7350 | | yellow produced by the hologram; ink image was |
| | | | masked by the hologram except at viewing angles |
| | | | where the hologram was washed out. |
| 17 | Coding Products | Magenta | Fair - The ink image was somewhat visible prior |
| | 7450 | | to tape-over as magenta color did not match with |
| | | | reddish hues produced by the overlying hologram |
| 18 | Source and product | Cyan | Fair - The cyan ink image was somewhat visible |
| | identification | | prior to tape-over as cyan ink color did not match |
| | unknown | | exactly with the bluish hues produced by the |
| | | | overlying hologram |
| 19 | DNP VW101 | Gold | Very Poor - Matte background reduced the |
| | Gold | Metallic | intensity of the holographic surface image and the |
| | | | underlying ink image was clearly visible prior to |
| | | | tape-over. |

From these tests, it was apparent that in order to improve the ability of an overlying hologram to mask an underlying printed image, the color of the ink can be selected to match closely to the prismatic colors generated by the hologram gratings Inks that don't match, including black, white, metallic and any colors with significant contrast relative to the refracted colors (e.g. Examples 17 and 18) are more likely to be visible through the overlying, surface-feature-generated holographic image. Also, the intensity of the overlying holographic image may be adjusted by the selection of the underlying substrate. For example, the use of the matte label stock as a base substrate produced a less intense (i.e., washed-out) hologram (see Example 19) relative to a hologram on a mirror-like underlying substrate (see Example 13). Generally, the more intense the overlying holographic image, the better the underlying ink image will be masked prior to tape-over.

### Example 20

A piece pressure sensitive adhesive (PSA) tape consisting of a 25 micron (1 mil) polyethylene backing and a 25 micron (1 mil) adhesive layer was laminated to the non-embossed surface of a piece of holographic film (ID #OPT-000N-16Z from Crown Roll Leaf) to form a film/adhesive/backing laminate. Next this adhesive-backed holographic film was die-cut to form the word “Void” in a repeating pattern. The die-cutting was done so that only the holographic film was cutting, leaving the underlying PSA tape intact. The continuous portion of the die-cut holographic film was removed to leave the discrete repeating pattern adhered to the adhesive of the PSA tape.

The backing was removed and the discrete pieces of the holographic film were laminated to the non-embossed surface of a second piece of the same type of holographic film. In this example the patterns of the two holographic films were held roughly in registration to one another, but this is not critical. This final stack was set on top of a polyester film with an optically thick coating of aluminum with a mirror finish such that the continuous holographic film provided the surface image, and the discrete portions of the holographic film formed the second, underlying image. The resulting structure was similar to that shown in FIG. 6.

The topmost holographic image (i.e., the surface-feature-generated image) was found to successfully obscure the secondary hologram image that comprised the “Void” message (i.e., the buried image). Next, a piece of clear box-sealing tape was adhered over a portion of the topmost holographic layer. In the area that had been taped over, the topmost holographic layer disappeared, thereby revealing the underlying image produced by the second holographic layer.

### Example 21

Example 21 illustrates an exemplary adjacent, duel-image tamper-indicating article according to some embodiments of the present disclosure. A piece of holographic film (ID #OPT-000N-16Z from Crown Roll Leaf) was uniformly metallized with titanium on the side opposite the embossed holographic image. This layer served as a contrast layer. Next, the embossed side of the film was selectively metallized with titanium so as to form the message “OPEN” in a repeating pattern. The selective metallization was done so as to produce a positive image (i.e. metallized letters with no metallization between the letters). The result was similar to that shown in FIG. 7a, with the selectively metallized layer serving as a refractive index modifying layer, wherein the first surface feature generated image comprises the uncovered portions of the holographic film (i.e., the portions between the letters) and the second, adjacent image comprised the covered portions of the holographic film (i.e., the letters forming the message “OPEN”).

It was observed that the repeating message pattern on the top side was obscured by the uniform metallization layer on the underside of the holographic film. That is, the holographic image visible on the top surface of the sample appeared uniform across the entire surface. Next, a piece of transparent box sealing tape was applied to the embossed and selectively metallized surface of the film. In the taped over region, the holographic image in the non-selectively metallized spaces disappeared, resulting in a smooth metallic appearance. In the metallized areas (i.e. the letters spelling “OPEN”), the holograms remained visible, thereby revealing the patterned image that had been selectively deposited on the embossed surface of the film.

### Example 22

Example 22 illustrates an exemplary buried, duel-image tamper-indicating article according to some embodiments of the present disclosure. The tamper indicating article of Example 22 includes a secondary tamper-indicating feature. 3M product #7384 is a commercially-available tamper-evident label stock. This product includes a base film and a clear release coating applied to selected portions of one major surface of the base film creating a repeating pattern of the word “VOID.” The release coat printed surface of the base film is the covered with an aluminum vapor coating creating a uniform metallic appearance.

A 20 gram batch of a matte LAB solution was prepared by mixing 12.8 g of isopropanol (IPA); 4.43 g of silicone-polyurea (20% by weight silicone) release agent (15% solids in IPA) and 2.75 g Chemisnow MR-2G (PMMA Microspheres, 33% by weight in IPA). The LAB formulation was coated onto the top surface of a 15 cm by 46 cm (6 inch by 18 inch) sheet of the 3M #7384 label stock using a number 4 Meyer Rod, thereby forming an LAB layer. The LAB layer had a surface-feature generated image corresponding to a uniform matte appearance.

Two 5 cm (2 inch) wide strips of this material were cut and applied to a corrugated cardboard surface. Next, a 5 cm (2 inch) wide piece of 3M #311 box sealing tape was applied across the two strips. In the taped over regions the appearance of the constructions changed from matte to shiny, giving an indication of tape-over.

Next, one end of one of the strips of Example 22 was peeled away from the cardboard substrate. This resulted in substantial fiber pull and there was no change of appearance of the tape, e.g., the hidden image present in the 7384 label stock did not appear. Finally, the other strip of Example 22 was frozen by turning an aerosol can upside down and spraying the propellant onto the tape. (A common form of tampering.) While the tape was frozen, one end of the strip was peeled away from the cardboard substrate. This time, an internal delamination occurred within the 3M #7384 layer of Example 22, which revealed the hidden message within it.

Various modifications and alterations of this invention will become apparent to those skilled in the art without departing from the scope and spirit of this invention.

1-33. (canceled)

34. A tamper indicating article comprising:
a substrate comprising a first major surface and an opposite second major surface;
a surface-feature image-generating layer associated with the first major surface of the substrate; and
an adhesive layer associated with the second major surface of the substrate,
wherein the surface-feature image-generating layer generates a visible, surface-feature-generated image comprising a hologram or a matte appearance upon interaction with light.

35. The tamper indicating article of claim 34, further comprising an underlying image associated with the second major surface of the substrate or with a surface of a second substrate.

36. The tamper indicating article of claim 35, wherein the surface-feature image-generating layer is integral to the first major surface of the substrate.

37. The tamper indicating article of claim 35, wherein the surface-feature image-generating layer comprises a resin layer associated with the first major surface of the substrate.

38. The tamper indicating article of claim 35, wherein the visible, surface-feature-generated image comprises a hologram.

39. The tamper indicating article of claim 35, wherein the visible, surface-feature-generated image comprises a matte appearance.

40. The tamper indicating article of claim 35, further comprising a functional layer having a thickness of less than 150 nanometers associated with the surface-feature image-generating layer, wherein the functional layer is a release layer or a hard coat.

41. The tamper indicating article of claim 35, further comprising a contrast layer located between the second major surface of the substrate and the adhesive layer.

42. The tamper indicating article of claim 41, wherein contrast layer comprises a material selected from the group consisting of metal, metal oxide, metal sulfide, and combinations thereof.

43. The tamper indicating article of claim 41, wherein the contrast layer comprises at least one of a dye or a pigment.

44. The tamper indicating article of claim 41, wherein the contrast layer is located between the underlying image and the adhesive.

45. The tamper indicating article of claim 35, wherein the surface-feature image-generating layer comprises an embossed layer.

46. The tamper indicating article of claim 35, wherein the surface-feature image-generating layer comprises inorganic particles dispersed in an organic resin.

47. The tamper indicating article of claim 35, wherein at least 80% of the features of the surface-feature image-generating layer have a z-axis dimension of between 0.09 micrometers and 2 micrometers.

48. The tamper indicating article of claim 35, wherein the refractive index of the surface-feature image-generating layer is between 1.4 and 1.5.

49. The tamper indicating article of claim 35, wherein the surface-feature image-generating layer generates the visible, surface-feature-generated image upon interaction with diffuse visible light.

50. The tamper indicating article of claim 35, wherein the underlying image comprises an ink.

51. The tamper indicating article of claim 35, wherein the underlying image comprises a hologram.

52. A tamper indicating article of claim 35, further comprising a refractive index modifying layer covering a first portion of the surface features.
